(19) United States
(12) Patent Application Publication
(10) Pub. No.: US 2007/0222923 A1
(43) Pub. Date: Sep. 27, 2007

(54) Electronic device having black layers

(76) Inventors: Jian Wang, Goleta, CA (US); Gang Yu, Santa Barbara, CA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/644,063

(22) Filed: Dec. 22, 2006

Related U.S. Application Data
(60) Provisional application No. 60/754,470, filed on Dec. 28, 2005.

(51) Int. Cl. G02F 1/1333

(52) U.S. Cl. 349/110

(57) ABSTRACT

An electronic device can include a control circuit of a pixel, a first black layer including an opening, and a second black layer. The control circuit can lie at an elevation between the first black layer and the second black layer. A process of forming an electronic device can include forming a first black layer over a substrate, wherein the first black layer includes an opening. The process can also include forming a control circuit of a pixel over the substrate after forming the first black layer. The process can further include forming a second black layer over the substrate after forming the control circuit.

### CROSS REFERENCE TO RELATED APPLICATIONS

This application claims the benefit of priority under 35 U.S.C. § 119(e) from provisional U.S. Application No. 60/754,470, “Electronic Device Having Black Layers”, Wang, et al, filed Dec. 28, 2005, which is incorporated herein by reference in its entirety.

### BACKGROUND INFORMATION

1. Field of the Disclosure

This disclosure relates in general to electronic devices, and more particularly, to electronic devices having black layers.

2. Description of the Related Art

An electronic device can include a liquid crystal display (“LCD”), an organic light-emitting diode (OLED) display, or the like. LCDs and OLED displays are promising technologies for flat panel display applications. Reflected ambient radiation can be a problem to users of the displays. One or more materials used for electrodes within the displays can have mirror-like reflectivity if its thickness is over 20 nanometers. The high reflectivity can result in poor readability or low contrast of the devices in lighted environments, and particularly when used outdoors.

An attempt to solve the reflection problem is to place a circular polarizer in front of the display panel. However, circular polarizers can block about 60% of the emitted light from the OLED and increase module thickness and cost considerably. The polarizer is typically located such that the substrate lies between the polarizer and the OLED.

Another attempt in improving display contrast includes using a light absorbing material between pixels of an electroluminescent display. The electrodes may lie at locations between such light absorbing material. Thus, the reflection from one or more electrodes may still be a problem because the electrode(s) may include portions that are as large or larger than the size of a pixel.

### SUMMARY

An electronic device can include a control circuit of a pixel, a first black layer including an opening, and a second black layer. The control circuit can lie at an elevation between the first black layer and the second black layer. A process of forming an electronic device can include forming a first black layer over a substrate, wherein the first black layer includes an opening. The process can also include forming a control circuit of a pixel over the substrate after forming the first black layer. The process can further include forming a second black layer over the substrate after forming the control circuit.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes a circuit schematic for a portion of an electronic device.

FIG. 2 includes an illustration of a cross-sectional view of a portion of a substrate after forming a black layer over a portion of the substrate.

FIG. 3 includes an illustration of a cross-sectional view of the substrate of FIG. 2 after forming conductive members for portions of a control circuit.

FIG. 4 includes an illustration of a cross-sectional view of the substrate of FIG. 8 after forming a dielectric layer and a semiconductor layer.

FIG. 5 includes an illustration of a cross-sectional view of the substrate of FIG. 4 after forming conductive members for other portions of the control circuit.

FIG. 6 includes an illustration of a cross-sectional view of the substrate of FIG. 5 after forming a portion of an insulating layer, a conductive plug, and a portion of a first electrode.

FIG. 7 includes an illustration of a cross-sectional view of the substrate of FIG. 6 after forming a portion of an organic layer over the first electrode.

FIG. 8 includes an illustration of a cross-sectional view of the substrate of FIG. 7 after forming a portion of a second electrode.

FIG. 9 includes an illustration of a cross-sectional view of the substrate of FIG. 8 after forming a substantially completed electronic device.

FIGS. 10 to 11 include illustrations of views of a portion of a substrate including a different black layer in accordance with an alternative embodiment.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

In a first aspect, an electronic device can include a control circuit of a pixel, a first black layer including an opening, and a second black layer. The control circuit can lie at an elevation between the first black layer and the second black layer.

In one embodiment of the first aspect, the pixel can include a first electrode. The first electrode can include a portion of the second black layer, and the first electrode can be electrically coupled to the control circuit. In a particular embodiment, the pixel can further include a second electrode that is electrically connected to the control circuit. In another embodiment, the electronic device can further include a substrate including a user surface that lies closer to the first black layer as compared to the second black layer.

In still another embodiment of the first aspect, the opening within the first black layer can correspond to a user radiation path of the pixel, wherein at least a portion of the control circuit lies within the user radiation path of the pixel. The control circuit can include a power transistor that includes a channel region, wherein at least a majority of the channel region lies outside the user radiation path. In a particular embodiment, the control circuit can include a charge storage component, wherein at least a portion of the charge storage component lies within the user radiation path of the pixel. In a more particular embodiment, at least a majority of the charge storage component may lie within the user radiation path, and substantially all of the channel region may lie outside the user radiation path. In a further embodiment, the first black layer, the second black layer, or both can be substantially opaque to radiation within the visible light spectrum. In still a further embodiment, the pixel can include an organic active layer.

In yet a further embodiment of the first aspect, the electronic device can further include a substrate having a user side. The pixel can include a first electrode and a second electrode, the second electrode can be electrically connected to the control circuit, and each of the first and second electrodes may lie farther from the user side of the substrate as compared to each of the first and second black layers. In a particular embodiment, the second black layer can include an opening corresponding to an emissive radiation path of the pixel, wherein at least a portion of the control circuit may lie outside the emissive radiation path of the pixel. In a more particular embodiment, the control circuit can include a power transistor that includes a channel region, wherein at least a majority of the channel region may lie outside the emissive radiation path. In an even more particular embodiment, the control circuit can include a charge storage component, wherein at least a portion of the charge storage component may lie within the emissive radiation path of the pixel. In a still more particular embodiment, at least a majority of the charge storage component may lie within the emissive radiation path, and substantially all of the channel region may lie outside the emissive radiation path.

In a second aspect, a process of forming an electronic device can include forming a first black layer over a substrate, wherein the first black layer includes an opening. The process can also include forming a control circuit of a pixel over the substrate after forming the first black layer. The process can further include forming a second black layer over the substrate after forming the control circuit.

In one embodiment of the second aspect, the process can further include forming a first electrode after forming the control circuit and before forming the second black layer, and forming a second electrode after forming the first electrode, wherein forming the second electrode includes forming the second black layer. In another embodiment, the first electrode can be electrically connected to the control circuit.

In still another embodiment of the second aspect, the second black layer can include an opening that is substantially coterminous with the opening of the first black layer. The process can further include forming a first electrode after forming the control circuit and forming the second black layer. The process can further include forming a second electrode after forming the first electrode. In a further embodiment, the electronic device can be configured to emit radiation or respond to radiation transmitted through the substrate. In still a further embodiment, the process can further include forming an organic active layer over the substrate after forming the first black layer and forming the control circuit.

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by Materials for One or More Black Layers, Circuit Diagram, Fabrication of an Electronic Device, Operating the Electronic Devices, Alternative Embodiments, and finally Benefits.

1. Definitions and Clarification of Terms

Before addressing details of embodiments described below, some terms are defined or clarified. The terms “array,” “peripheral circuitry,” and “remote circuitry” are intended to mean different areas or components of an electronic device. For example, an array may include pixels, cells, or other structures within an orderly arrangement (usually designated by columns and rows). The pixels, cells, or other structures within the array may be controlled by peripheral circuitry, which may lie on the same substrate as the array but outside the array itself. Remote circuitry typically lies away from the peripheral circuitry and can send signals to or receive signals from the array (typically via the peripheral circuitry). The remote circuitry may also perform functions unrelated to the array. The remote circuitry may or may not reside on the substrate having the array.

The term “black layer” is intended to mean a layer, by itself or in combination with one or more other layers, that allows no more than approximately 10% of radiation at a targeted wavelength or spectrum of wavelengths that is incident on such layer, or combination, to be reflected outside the electronic device or received by a protected region (e.g., a channel region of a transistor) within the electronic device.

The term “channel region” is intended to mean a region lying between source/drain regions of a field-effect transistor, whose biasing, via a gate electrode of the field-effect transistor, affects the flow of carriers, or lack thereof, between the source/drain regions.

The term “charge storage component” is intended to mean an electronic component configured to store a charge for at least a period of time. An example of a charge storage component includes a capacitor or a transistor structure biased to act as a capacitor.

The term “control circuit” is intended to mean a circuit within an array of pixels or subpixels that controls the signal(s) for no more than one pixel. In one embodiment, each pixel has one control circuit, and in another embodiment, each subpixel has one control circuit

The term “coterminous” is intended to mean having the same or coincident boundaries.

The term “electrically connected,” or any variant thereof, with respect to electronic components, circuits, or portions thereof, is intended to mean that two or more electronic components, circuits, or any combination of at least one electronic component and at least one circuit do not have any intervening electronic component lying between them. Parasitic resistance, parasitic capacitance, or both are not considered electronic components for the purposes of this definition. In one embodiment, electronic components are electrically connected when they are electrically shorted to one another and are at substantially the same voltage. Note that “electrically connected” includes one or more connections that allow optical signals to be transmitted. For example, electronic components can be electrically connected together using fiber optic lines to allow optical signals to be transmitted between such electronic components.

The term “electrically coupled,” or any variants thereof, is intended to mean an electrical connection, linking, or association of two or more electronic components, circuits, systems, or any combination of: (1) at least one electronic component, (2) at least one circuit, or (3) at least one system in such a way that a signal (e.g., current, voltage, or optical signal) may be transferred from one to another. A non-limiting example of “electrically coupled” can include a direct electrical connection between electronic component(s), circuit(s) or electronic component(s) or circuit(s) with switch(es) (e.g., transistor(s)) electrically connected between them.

The term “electrode” is intended to mean a member, a structure, or a combination thereof configured to transport carriers within an electronic component. For example, an electrode may be an anode, a cathode, a capacitor electrode, a gate electrode, etc. An electrode may include a part of a transistor, a capacitor, a resistor, an inductor, a diode, an electronic component, a power supply, or any combination thereof.

The term “electronic component” is intended to mean a lowest level unit of a circuit that performs an electrical or electro-radiative (e.g., electro-optic) function. An electronic component may include a transistor, a diode, a resistor, a capacitor, an inductor, a semiconductor laser, an optical switch, or the like. An electronic component does not include parasitic resistance (e.g., resistance of a wire) or parasitic capacitance (e.g., capacitive coupling between two conductors electrically connected to different electronic components where a capacitor between the conductors is unintended or incidental).

The term “electronic device” is intended to mean a collection of circuits, electronic components, or combinations thereof that collectively, when properly electrically connected and supplied with the appropriate potential(s), performs a function. An electronic device may be included or be part of a system. An example of an electronic device includes a display, a sensor array, a computer system, an avionics system, an automobile, a cellular phone, other consumer or industrial electronic products, or any combination thereof.

The term “elevation” is intended to mean a distance from a primary surface of a substrate as measured in a direction perpendicular to the primary surface.

The term “emissive radiation path” is intended to mean a path wherein radiation can travel from a radiation emission region to a user side of a substrate. The edges of the emissive radiation path are substantially perpendicular to the user surface of the substrate.

The term “field-effect transistor” is intended to mean a transistor, whose current carrying characteristics are affected by a voltage on a gate electrode. A field-effect transistor includes a junction field-effect transistor (JFET) or a metal-insulator-semiconductor field-effect transistor (MISFET), including a metal-oxide-semiconductor field-effect transistor (MOSFETs), a metal-nitride-oxide-semiconductor (MNOS) field-effect transistor, or the like. A field-effect transistor can be n-channel (n-type carriers flowing within the channel region) or p-channel (p-type carriers flowing within the channel region). A field-effect transistor may be an enhancement-mode transistor (channel region having a different conductivity type compared to the transistor's source/drain regions) or depletion-mode transistor (the transistor's channel and source/drain regions have the same conductivity type).

The term “opaque” is intended to mean that at least 90% of the radiation at a targeted wavelength or spectrum that is incident on a layer or other object is absorbed by such layer or other object. An opaque layer can be a specific type of black layer.

The term “organic active layer” is intended to mean one or more organic layers, wherein at least one of the organic layers, by itself, or when in contact with a dissimilar material is capable of forming a rectifying junction.

The term “organic layer” is intended to mean one or more layers, wherein at least one of the layers comprises a material including carbon and at least one other element, such as hydrogen, oxygen, nitrogen, fluorine, etc.

The term “power transistor” is intended to mean a transistor that is configured to regulate another electronic component. For example, in an OLED display, a power transistor regulates the amount of current that flows through a corresponding OLED within the OLED display.

The term “primary surface” is intended to mean a surface of a substrate from which an electronic component is subsequently formed.

The term “radiation-emitting component” is intended to mean an electronic component, which when properly biased, emits radiation at a targeted wavelength or spectrum of wavelengths. The radiation may be within the visible-light spectrum or outside the visible-light spectrum (UV or IR). A light-emitting diode is an example of a radiation-emitting component.

The term “radiation-responsive component” is intended to mean an electronic component, which when properly biased, can respond to radiation at a targeted wavelength or spectrum of wavelengths. The radiation may be within the visible-light spectrum or outside the visible-light spectrum (UV or IR). An IR sensor and a photovoltaic cell are examples of radiation-sensing components.

The term “rectifying junction” is intended to mean a junction within a semiconductor layer or a junction formed by an interface between a semiconductor layer and a dissimilar material, in which charge carriers of one type flow easier in one direction through the junction compared to the opposite direction. A pn junction is an example of a rectifying junction that can be used as a diode.

The term “source/drain region” is intended to mean a region of a field-effect transistor that injects charge carriers into a channel region or receives charge carriers from the channel region. A source/drain region can include a source region or a drain region, depending on the flow of current through the field-effect transistor. A source/drain region may act as source region when current flows in one direction through the field-effect transistor, and as a drain region when current flows in the opposite direction through the field-effect transistor.

The term “substrate” is intended to mean a workpiece that can be either rigid or flexible and may include one or more layers of one or more materials, which can include, but are not limited to, glass, polymer, metal or ceramic materials or combinations thereof.

The term “user radiation path” is intended to mean a path wherein radiation outside an electronic device can be transmitted from a user side of a substrate to a radiation emissive region or a radiation responsive region, or a path wherein radiation can be emitted from or reflected by an electronic component within the electronic device to the user side of the substrate. The edges of the user radiation path are substantially perpendicular to the user surface of the substrate.

The term “user surface” is intended to mean a surface of the electronic device principally used during normal operation of the electronic device. In the case of a display, the surface of the electronic device seen by a user would be a user surface. In the case of a sensor or photovoltaic cell, the user surface would be the surface that principally transmits radiation that is to be sensed or converted to electrical energy. Note that an electronic device may have more than one user surface.

The term “visible light spectrum” is intended to mean a radiation spectrum having wavelengths corresponding to 400 to 700 nm.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts. Concepts related to reflection, contrast ratio, and other similar principles are described in more detail in U.S. patent application Ser. No. 10/658,236 entitled “Organic Electronic Device Having Low Background Luminance” by Yu et al. filed Sep. 8, 2003 (herein, “Yu”).

3. Materials for One or More Black Layers

A wide variety of materials can be used for a black layer. The electrical characteristics of potential materials can vary from conductive to resistive to insulating. A potential material for a black layer can comprise one or more inorganic materials including an elemental metal (e.g., W, Ta, Cr, Ru, In, etc.); a metal alloy (e.g., Mg—Al, Li—Al, etc.); a metal oxide (e.g., CrₓO_{y}, FeₓO_{y}, In₂O₃, SnO, ZnO, etc.); a metal alloy oxide (e.g., InSnO, AlZnO, AlSnO, etc.); a metal nitride (e.g., AlN, WN, TaN, TiN, etc.); a metal alloy nitride (e.g., TiSiN, TaSiN, etc.); a metal oxynitride (e.g., AlON, TaON, etc.); a metal alloy oxynitride; a Group 14 oxide (e.g., SiO₂, GeO₂, etc.); a Group 14 nitride (e.g., Si₃N₄, silicon-rich Si₃N₄, etc.); a Group 14 oxynitride (e.g., silicon oxynitride, silicon-rich silicon oxynitride, etc.); a Group 14 material (e.g., graphite, Si, Ge, SiC, SiGe, etc.); a Group 13-15 semiconductor material (e.g., GaAs, InP, GalnAs, etc.); a Group 12-16 semiconductor material (e.g., ZnSe, CdS, ZnSSe, etc.); or any combination thereof.

An elemental metal refers to a layer that consists essentially of a single element and is not a homogenous alloy with another metallic element or a molecular compound with another element. For the purposes of metal alloys, silicon is considered a metal. In many embodiments, a metal, whether as an elemental metal or as part of a molecular compound (e.g., metal oxide, or metal nitride), may be a transition metal (an element within Groups 3 through 12 in the Periodic Table of the Elements) including chromium, tantalum, or gold.

A potential material for a high absorbance layer can comprise one or more organic materials including a polyolefin (e.g., polyethylene, polypropylene, etc.); a polyester (e.g., polyethylene terephthalate, polyethylene naphthalate, etc.); a polyimide; a polyamide; a polyacrylonitrile or polymethacrylonitrile; a perfluorinated or partially fluorinated polymer (e.g., polytetrafluoroethylene, a copolymer of tetrafluoroethylene and a polystyrene); a polycarbonate; a polyvinyl chloride; a polyurethane; a polyacrylic resin, including a homopolymer or a copolymer of an ester of an acrylic or methacrylic acid; an epoxy resin; a Novolac resin, an organic charge transfer compound (e.g., tetrathiafulvalene tetracyanoquinodimethane (“TTF-TCNQ”), etc.); or any combination thereof.

After selecting a material, skilled artisans appreciate that the thickness of the material can be tailored to achieve low L_{background} using one or more of the equations in Yu. Although the calculations can yield a single thickness, typically a range of acceptable thicknesses may be given for manufacturing reasons. As long as the thickness does not lie outside the range, reasonably acceptable L_{background} may be achieved.

Skilled artisans appreciate that they may be able to achieve L_{background} without having to change the composition of materials of the layers currently used. Such a change could cause problems with device performance, problems with processing or materials incompatibility, an entire re-design of the organic electronic device, or the like. The thicknesses for layers can be chosen to give acceptable electrical and radiation-related performance. For example, electrodes may have a minimum thickness determined by resistance, electromigration, or other device performance or reliability reasons. The maximum thickness may be limited by step-height concerns, such as step coverage or lithography constraints for subsequently-formed layers. Still, the range between the minimum and maximum thicknesses for an electrode layer may allow a plurality of thicknesses to be chosen that still give low L_{background} while achieving the proper device performance.

In another embodiment, an opaque layer, which is a specific type of black layer, can be used. For an opaque layer, at least 90% of the radiation at the targeted wavelength or spectrum of wavelengths is absorbed by the opaque layer. In one embodiment, the opaque layer can act as a black layer and achieve low L_{background}. As will be described later in this specification, an opaque layer may be used as a black layer where radiation transmission in either direction is undesired.

4. Circuit Diagram

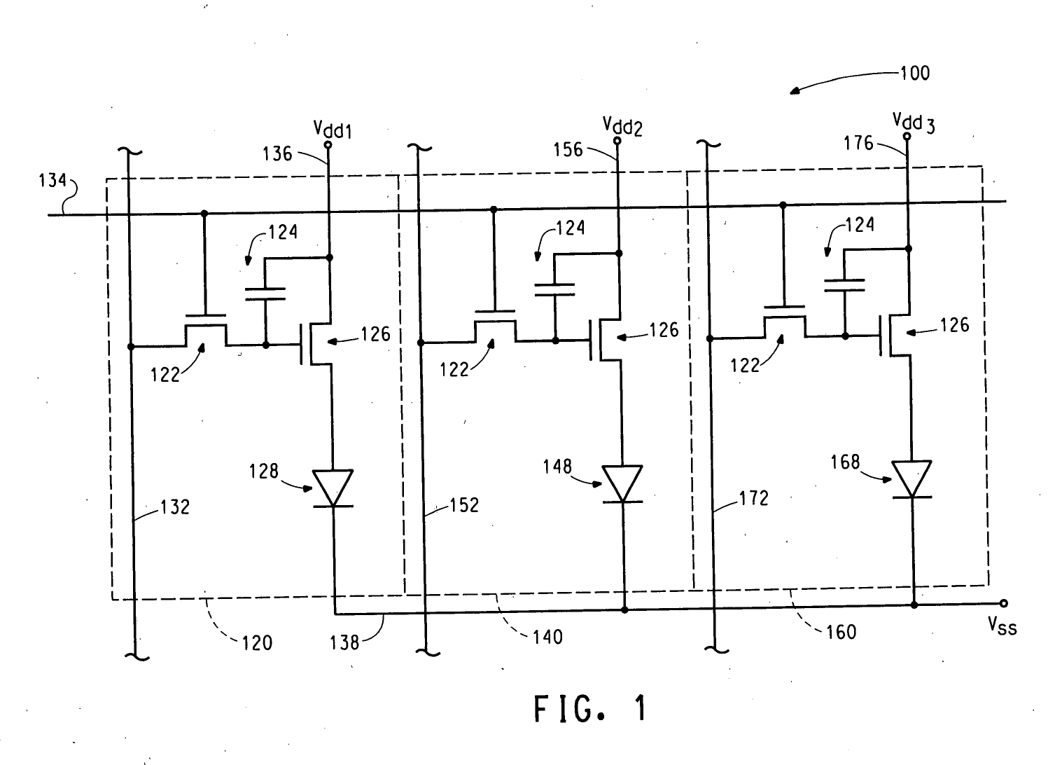

FIG. 1 includes a circuit diagram of a portion of an electronic device 100. The electronic device 100 includes a first pixel 120, a second pixel 140, and a third pixel 160. Each of the pixels 120, 140, and 160 includes a pixel circuit as illustrated in FIG. 1. Each pixel circuit includes a pixel driving circuit and an electronic component 128, 148, or 168.

The first pixel 120 includes a select transistor 122, a charge storage component 124, a power transistor 126, and an electronic component 128. The charge storage component 124 can include a capacitor or a transistor structure configured to act as a capacitor (e.g., source and drain regions electrically connected to each other or biased to substantially the same voltage). The charge storage component 124 is illustrated as a capacitor to simplify, but not limit, the description herein. The electronic component 128 can be nearly any electronic component that is driven by an electrical current. In one embodiment, the electronic component 128 is a radiation-emitting component, such as an OLED. Within pixel 120, the pixel driving circuit includes the select transistor 122, the charge storage component 124, and the power transistor 126.

The select transistor 122 includes a gate electrode connected to a select line (“SL”) 134, a first source/drain region connected to a data line (“DL”) 132, and a second source/drain region connected to a first electrode of the charge storage component 124, and a gate electrode of the power transistor 126. SL 134 provides a control signal for the select transistor 122, and DL 132 provides a data signal to be passed to the charge storage component 124 and the gate electrode of the power transistor 126 when the select transistor 122 is activated.

The charge storage component 124 includes the first electrode and a second electrode. The first electrode of the charge storage component 124 is connected to the second source/drain region of the select transistor 122 and the gate electrode of the power transistor 126. The second electrode of the charge storage component 124 is connected to a first power supply line, which in one embodiment is a V_{dd1} line 136. In an alternative embodiment (not illustrated), an optional anti-degradation unit may be connected to the charge storage component 124 and at least one of the power supply lines (e.g., Vₛₛ line 138, V_{dd1} line 136, or both) connected to the pixel 120.

The power transistor 126 includes the first gate electrode, a first source/drain region, and a second source/drain region. The first source/drain region of the power transistor 126 is connected to a first electrode of the electronic component 128, and the second source/drain region of the power transistor 126 is coupled to the V_{dd1} line 136. In one embodiment, the second source/drain region of the power transistor 126 is connected to the V_{dd1} line 136. In another embodiment, the optional anti-degradation unit may be connected to the second source/drain region of the power transistors 126 and the V_{dd1} line 136.

The electronic component 128 includes the first electrode and a second electrode that is connected to the Vₛₛ line 138. In one embodiment, the first electrode is an anode, and the second electrode is a cathode. In another embodiment, the electronic component 128 is an organic, radiation-emitting electronic component, such as an OLED. The rest of the pixel circuit, which is the pixel driving circuit in one embodiment, is well suited for providing a variable current source to drive the electronic component 128. Therefore, one or more electronic components that are current driven may be used in place of or in conjunction with the electronic component 128. Note that one or more electronic components may or may not include a diode.

In another embodiment (not illustrated), the electronic component 128 and power transistor 126 may be reversed. More specifically, (1) the first electrode (e.g., anode) of the electronic component 128 is connected to the V_{dd1} line 136, (2) the second electrode (e.g., cathode) of the electronic component 128 is connected to one of the source/drain regions of the power transistor 126, and (3) the other source/drain region of the power transistor 126 is connected to the Vₛₛ line 138.

The second pixel 140 is similar to the first pixel 120 except that, within the second pixel 140, a data line 152 is connected to a first source/drain region of the select transistor 122, a V_{dd2} line 156 is connected to a second source/drain region of the power transistor 126, and an electronic component 148 is connected between a first source/drain region of the power transistor 126 and the Vₛₛ line 138. The third pixel 160 is similar to the first and second pixels 120 and 140 except that, within the third pixel 160, a data line 172 is connected to a first source/drain region of the select transistor 122, a V_{dd3} line 176 is connected to a second source/drain region of the power transistor 126, and an electronic component 168 is connected between a first source/drain region of the power transistor 126 and the Vₛₛ line 138.

In one embodiment, the electronic components 128, 148, 168 are substantially identical to one another. In another embodiment, the electronic components 128, 148, and 168 are different from one another. For example, the electronic component 128 is a blue light-emitting component, the electronic component 148 is a green light-emitting component, and the electronic component 168 is a red light-emitting component. The V_{dd1}, V_{dd2}, and V_{dd3} lines 136, 156, and 176 may be at the same or different voltages compared to one another. In another embodiment (not illustrated), the second electrodes of the electronic components 128, 148, 168 may be connected to different power supply lines that may operate at substantially the same or significantly different voltages. After reading this specification, skilled artisans will be able to design the electronic device 100 to meet the needs or desires for a specific application.

The select transistor 122, power transistor 126, or any combination thereof can include a field-effect transistor. In the circuit for the pixel, as illustrated in FIG. 1, all transistors are n-channel transistors. Any one or more of the n-channel transistors can be replaced by any one or more p-channel transistors. In other embodiments, other transistors (including one or more JFETs, one or more bipolar transistors, or any combination thereof) may be used within the select transistor 122.

5. Fabrication of an Electronic Device

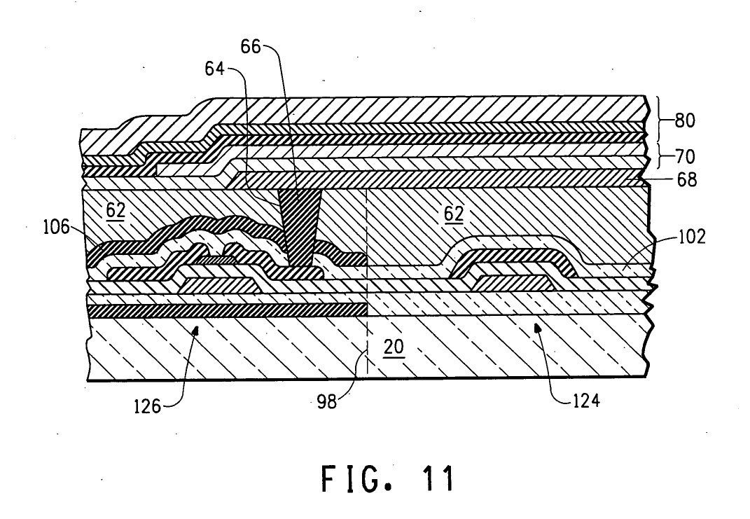

Attention is now directed to details for a first set of embodiments that is illustrated in FIGS. 2 through 8 in which low L_{background} and hence high contrast can be achieved by using a plurality of black layers. FIGS. 9 and 10 include an alternative embodiment in which an additional black layer may be used.

FIG. 2 includes an illustration of a cross-sectional view of a portion of a partially completed electronic device after forming a black layer 26 over a portion of a substrate 20. The substrate 20 can be either rigid or flexible and may include one or more layers of one or more materials, which can include glass, polymer, metal or ceramic materials, or any combination thereof. In one embodiment, the substrate 20 is substantially transparent to a targeted wavelength or spectrum of wavelengths associated with the electronic device. For example, the electronic device may emit radiation within the visible light spectrum, and thus, the substrate 20 would be transparent to radiation within the visible light spectrum. In another example, the electronic device may respond to infrared radiation, and thus the substrate 20 would be transparent to the infrared radiation.

The substrate 20 includes a user surface 22 and a primary surface 24. The user surface 22 can be the surface of the substrate 20 seen by a user when using the electronic device. The primary surface 24 can be a surface from which at least some of the electronic components for the electronic device may be fabricated.

The black layer 26 can include any one or more of the materials that can be used for a black layer as previously described. In one embodiment, the black layer 26 can be opaque because radiation may not need to pass either way through the black layer 26. In another embodiment, the black layer 26 should have low absorbance because radiation from a subsequently-formed, radiation-emitting component may be designed to transmit through the black layer 26 during the operation of the electronic device.

The black layer 26 may be formed using one or more conventional or proprietary deposition techniques, patterning techniques, or a combination thereof. The thickness of the black layer 26 may be in a range of 2 to 1000 nm. The thickness can be greater or less than the range above, if needed or desired. For example, an upper limit on thickness may be determined based on considerations unrelated to radiation, such as planarity of the uppermost surface when forming a subsequent layer, and when such, the thickness could be more than 10 microns.

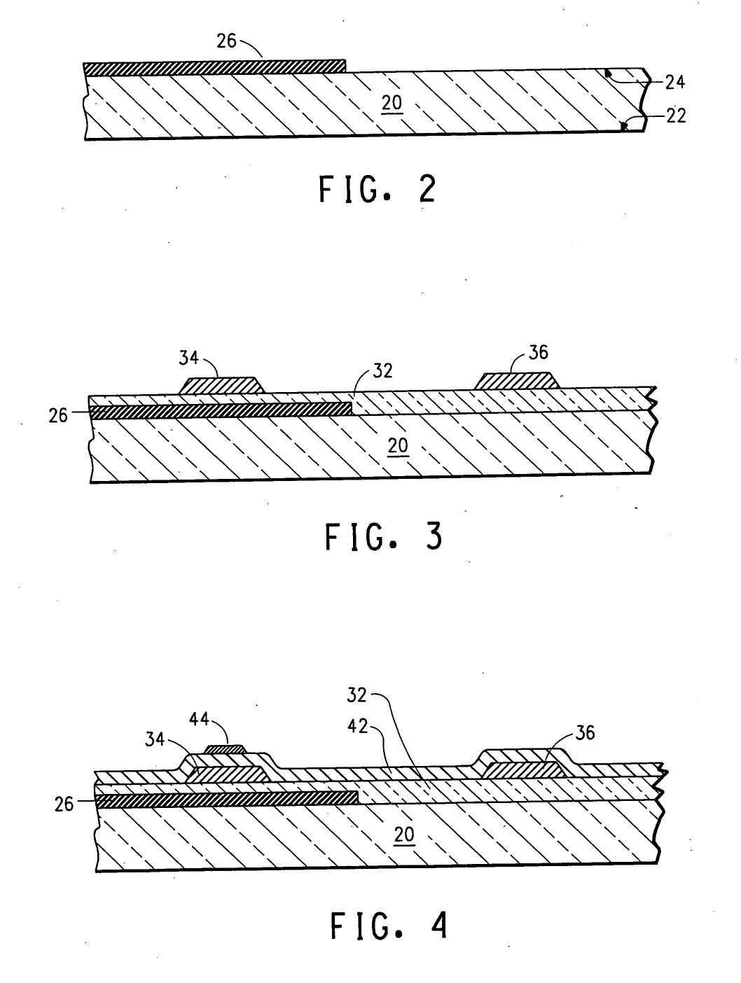

An optional insulating layer 32 can be formed over the black layer 26, and conductive members 34 and 36 may be formed over the insulating layer 32, as illustrated in FIG. 3. The insulating layer 32 can include an organic material, an inorganic material, or a combination thereof. The composition, formation (e.g., deposition), and thickness of the insulating layer 32 can be conventional or proprietary. If the black layer 26 is conductive or resistive, the insulating layer 32 can be thick enough (e.g., at least 1 nm) to substantially prevent a leakage path between spaced apart conductive members that overlie the black layer 26. If the black layer 26 is an insulator, the insulating layer 32 may be eliminated.

In one embodiment, the conductive member 34 includes at least a portion that acts as a gate electrode for a switch transistor or power transistor, as illustrated in FIG. 1. Another portion of the conductive member 34 may act as a local interconnect, a capacitor electrode, or the like. In one embodiment, the conductive member 36 includes at least a portion that acts as a capacitor electrode for a charge storage component, such as a capacitor, as illustrated in FIG. 1. Another portion of the conductive member 36 may act as a local interconnect, a gate electrode, or the like.

The conductive members 34 and 36 may include one or more conventional or proprietary materials used for electrodes in a LCD or OLED display. The conductive members 34 and 36 can be formed by deposition using a conventional or proprietary technique. The thickness of the conductive members 34 and 36 may be in a range of 20 to 1000 nm. The thickness can be greater or less than the range above, if needed or desired. For example, an upper limit on thickness may be determined based on considerations unrelated to radiation, such as electrical characteristics of the electronic components being formed and the composition of the conductive members 34 and 36, and when such, could be more than 10 microns. The conductive member 34, conductive member 36, or both may be transparent or opaque to radiation at the targeted wavelength or spectrum of wavelengths. For example, the conductive member 36 may lie within a subsequently-formed user radiation path, and the conductive member 36 may be transparent to radiation within the visible light spectrum. The conductive members 34 and 36 may have the same or different compositions, the same or different thicknesses, may be formed substantially simultaneously or at different times, or any combination thereof.

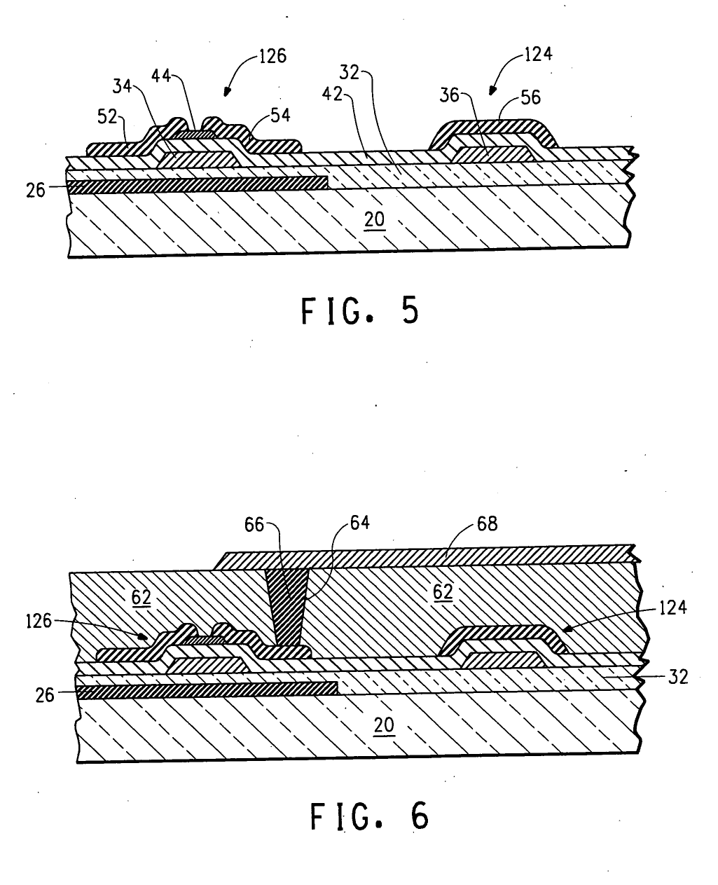

A dielectric layer 42 and a semiconductor region 44 can be formed after forming the conductive members 34 and 36, as illustrated in FIG. 4. A portion of the dielectric layer 42 that lies between the conductive member 34 and the semiconductor region 44 may act as a gate dielectric, and another portion of the dielectric layer 42 adjacent to the conductive member 36 may act as a capacitor dielectric.

The dielectric layer 42 can include one or more layers of one or more insulating materials, such as an oxide, a nitride, an oxynitride, or any combination thereof. The dielectric layer 42 can be formed by deposition using a conventional or proprietary technique. The thickness of the dielectric layer 42 may be in a range of 2 to 100 nm. The thickness can be greater or less than the range above, if needed or desired.

The semiconductor layer 44 can include one or more layers of one or more semiconductor materials, such as a Group 14 material (e.g., Si, Ge, SiC, SiGe, etc.), a Group 13 to 15 semiconductor material (e.g., GaAs, InP, GaInAs, etc.), a Group 12 to 16 semiconductor material (e.g., ZnSe, CdS, ZnSSe, etc.), or any combination thereof. The semiconductor layer 44 may be intrinsic (no dopant or a doping concentration no greater than 10¹⁴ atoms/cm³) or lightly doped (doping concentration between 10¹⁴ to 10¹⁷ atoms/cm³) with an n-type or p-type dopant. The semiconductor layer 44 can be formed by deposition using a conventional or proprietary technique. The thickness of the semiconductor layer 44 may be in a range of 50 to 500 nm. The thickness can be greater or less than the range above, if needed or desired.

Conductive members 52, 54, and 56 are formed over the substrate 20, as illustrated in FIG. 5. The conductive members 52 and 54 may allow electrical connections to be made to the source/drain (“S/D”) regions of the transistor structure in FIG. 5 and may also include a dopant that can migrate into portions of the semiconductor layer 44 to form S/D regions within the semiconductor layer 44.

The conductive members 52 and 54 may include one or more layers with one or more compositions. Each of conductive members 52 and 54 can include a dopant that can migrate into portions of the semiconductor layer 44 to form S/D regions within the semiconductor layer 44. Other portions of the conductive members 52 and 54 may act as a local interconnect, a capacitor electrode, or the like. In one embodiment, the conductive member 56 includes at least a portion that acts as another capacitor electrode for a charge storage component, such as the capacitor, as illustrated in FIG. 5. Another portion of the conductive member 56 may act as a local interconnect, a gate electrode, or the like.

The conductive members 52 and 54 may include one or more conventional or proprietary materials used for S/D doping and electrical connections for thin-film transistor structures within LCD or OLED displays. The conductive member 56 may include one or more conventional or proprietary materials used for capacitor electrodes in a LCD or OLED display.

The conductive members 52, 54, and 56 can be formed by deposition using a conventional or proprietary technique. The thickness of the conductive members 52, 54, and 56 may in a range of 20 to 1000 nm. The thickness can be greater or less than the range above, if needed or desired. For example, an upper limit on thickness may be determine based on considerations unrelated to radiation, such as electrical characteristics of the electronic components being formed and the composition of the conductive members 52, 54, and 56, and when such, could be more than 10 microns. The conductive member 52, conductive member 54, conductive member 56, or any combination thereof may be transparent or opaque to radiation at the targeted wavelength or spectrum of wavelengths. For example, the conductive member 56 may lie within a subsequently-formed user radiation path, and the conductive member 56 may be transparent to radiation within the visible light spectrum. The conductive members 52, 54, and 56 may have the same or different compositions, the same or different thicknesses, may be formed substantially simultaneously or be formed at different times, or any combination thereof.

At this point in the process, a power transistor 126 and the charge storage component 124 have been formed. As illustrated in FIG. 5, the power transistor 126 includes the conductive member 34, the dielectric layer 42, the semiconductor layer 44, and conductive members 52 and 54. Also as illustrated in FIG. 5, the charge storage component 124 includes the conductive member 36, the dielectric layer 42, and the conductive member 56. Although not illustrated in FIG. 5, select transistors 122, other power transistors 126, and other charge storage components 124 are formed. In one embodiment as illustrated in FIG. 5, at least part of the power transistor 126 overlies the black layer 26, and at least part of the charge storage component 124 does not overlie the black layer 26. The significance of overlying and not overlying the black layer 26 will be described in more detail later in this specification.

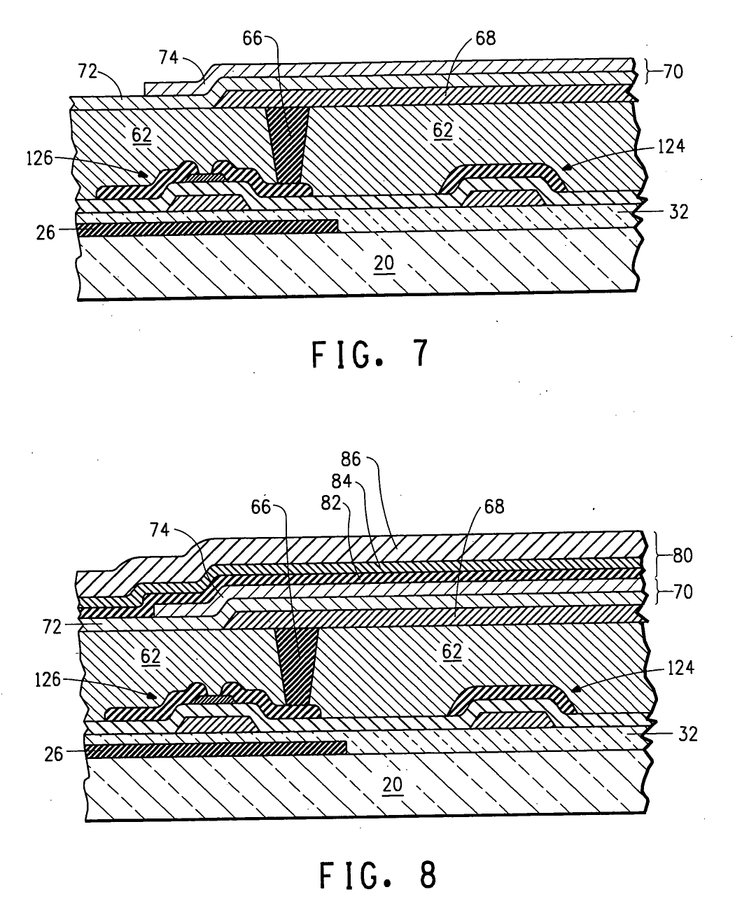

An insulating layer 62 is formed over the substrate 20, including the power transistor 126 and charge storage component 124, as illustrated in FIG. 6. The insulating layer 62 can be a planarization layer to allow a relatively flatter surface from which additional electronic components (e.g., OLEDS) may be formed. The insulating layer 62 can include one or more layers of an oxide, a nitride, an oxynitride or the like. The insulating layer 62 can be formed by deposition using a conventional or proprietary technique. The thickness of the insulating layer 62 may in a range of 100 to 5000 nm. The thickness can be greater or less than the range above, if needed or desired.

The insulating layer 62 can be patterned to form a contact opening 64 that extends to the conductive member 54 of the power transistor 126. The contact opening 64 can be formed using a conventional or proprietary lithographic technique. A conductive plug 66 can be formed to provide an electrical connection between the power transistor 126 and a subsequently-formed electronic component. The conductive plug 66 may or may not extend above the uppermost surface of the insulating layer 62. The conductive plug 66 may include one or more layers of one or more materials and may be formed by deposition using a conventional or proprietary technique to electrically connect control circuits within a back panel to its corresponding electrical components for pixels or subpixels of an LCD or OLED display. The conductive plug 66 may or may not substantially fill the opening 64. Other openings 64 and conductive plugs 66 are formed but are not illustrated in FIG. 6.

A first electrode 68 is formed over the conductive plug 66 and insulating layer 62, as illustrated in FIG. 6. In one embodiment, the first electrode 68 can act as an anode for an electronic component 128, 148, or 168, and includes one or more layers used as anodes within LCD or OLED displays. The first electrode 68 can be formed by a deposition using a conventional or proprietary technique. The first electrode 68 may have a thickness in a range of approximately 10 to 1000 nm. Other first electrodes for other electronic components 128, 148, or 168 are formed but are not illustrated in FIG. 6.

An organic layer 70 is formed over the first electrode 68 and substrate 20, as illustrated in FIG. 7. The organic layer 70 may include one or more layers. For example, the organic layer can include an organic active layer, a buffer layer, an electron-injection layer, an electron-transport layer, an electron-blocking layer, a hole-injection layer, a hole-transport layer, or a hole-blocking layer, or any combination thereof. In one embodiment, the organic layer 70 may include a first organic layer 72 and an organic active layer 74.

Any individual or combination of layers within the organic layer 70 can be formed by a conventional or proprietary technique, including spin coating, casting, vapor depositing (chemical or vapor), printing (ink jet printing, screen printing, solution dispensing (dispensing the liquid composition in strips or other predetermined geometric shapes or patterns, as seen from a plan view), or any combination thereof), other depositing techniques, or any combination thereof for appropriate materials as described below. Any individual or combination of layers within the organic layer 70 may be cured after deposition.

As illustrated in FIG. 7, the first organic layer 72 may act as a buffer layer, an electronic-blocking layer, a hole-injection layer, a hole-transport layer, or any combination thereof. In one embodiment, the first organic layer includes a single layer, and in another embodiment, the first organic layer 72 can include a plurality of layers. The first organic layer 72 may include one or more materials that may be selected depending on the function that the first organic layer 72 is to provide. In one embodiment, if the first organic layer 72 is to act as a buffer layer, the first organic layer 72 may include a conventional or proprietary material that is suitable for use in a buffer layer, as used in an OLED display. In another embodiment, if the first organic layer 72 is to act as a hole-transport layer, the first organic layer may include a conventional or proprietary material that is suitable for use in a hole-transport layer. In one embodiment, the thickness of the first organic layer 72 may have a thickness in a range of approximately 50 to 300 nm, as measured over the substrate 20 at a location spaced apart from the first electrode 68. In another embodiment, the first organic layer 72 may be thinner or thicker than the range recited above.

The composition of the organic active layer 74 can depend upon the application of the electronic device. In one embodiment, the organic active layer 74 is used in a radiation-emitting component. In a particular embodiment, the organic active layer 74 can include a blue light-emitting material, a green light-emitting material, or a red light-emitting material. Other organic active layers (not illustrated) for radiation at different targeted wavelengths or spectra of wavelengths, as compared to the organic active layer 74, can be formed. Although not illustrated, a structure (e.g., a well structure, cathode separators, or the like) may lie adjacent the first electrode 68 to reduce the likelihood of materials from different organic active layers from contacting each other at locations above the first electrode 68. For a monochromatic display, the organic active layers may have substantially the same composition. In another embodiment, the organic active layer 74 can be replaced by an organic active layer that is substantially continuous over the portion of the substrate 20 illustrated in FIG. 7. In another embodiment, the organic active layer 74 may be used in a radiation-responsive component, such as a radiation sensor, photovoltaic cell, or the like.

The organic active layer 74 and potentially other organic active layers can include material(s) conventionally used as organic active layers in organic electronic devices and can include one or more small molecule materials, one or more polymer materials, or any combination thereof. After reading this specification, skilled artisans will be capable of selecting appropriate material(s), layer(s) or both for the organic active layer 74 or potentially other organic active layers. In one embodiment, the organic active layers 74 or another potential organic active layer has a thickness in a range of approximately 40 to 100 nm, and in a more specific embodiment, in a range of approximately 70 to 90 nm.

In an alternative embodiment, the organic layer 70 may include a single layer with a composition that varies with thickness. For example, the composition nearest the first electrode 68 may act as a hole transporter, the next composition may act as an organic active layer, and the composition furthest from the first electrode 68 may act as an electron transporter. Similarly, the function of charge injection, charge transport, charge blocking, or any combination of charge injection, charge transport, and charge blocking can be incorporated into the organic layer 70. One or more materials may be present throughout all or only part of the thickness of the organic layer.

Although not illustrated, a hole-blocking layer, an electron-injection layer, an electron-transport layer, or any combination thereof may be part of the organic layer 70 and formed over the organic active layer 74. The electron-transport layer can allow electrons to be injected from the subsequently-formed second electrode (i.e., cathode) and transferred to the organic active layer 74. The hole-blocking layer, electron-injection layer, electron-transport layer, or any combination thereof typically has a thickness in a range of approximately 30 to 500 nm.

Any one or more of the layers within the organic layer 70 may be patterned using a conventional or proprietary technique to remove portions of the organic layer 70 where electrical contacts (not illustrated) are subsequently made. Typically, the electrical contact areas are near the edge of the array or outside the array to allow peripheral circuitry to send or receive signals to or from the array.

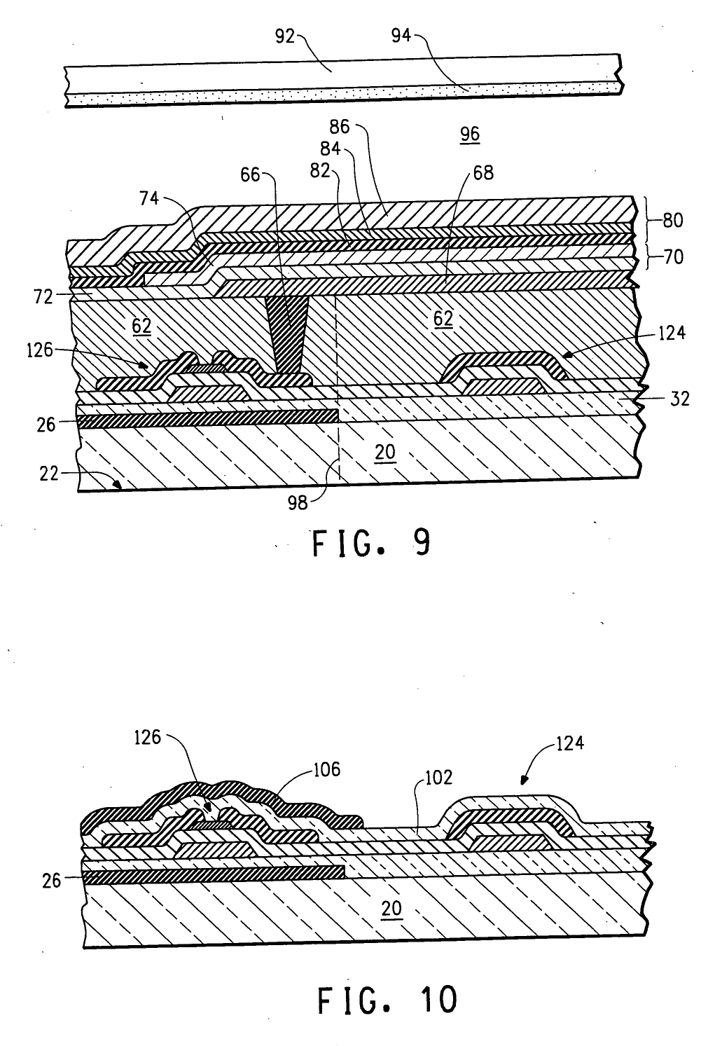

A second electrode 80 is formed over the organic layer 70, as illustrated in FIG. 8. The second electrode can act as a cathode for the electronic component being formed. In one embodiment, the electronic component is a radiation-emitting component, a radiation-responsive component, or the like. In a particular embodiment, the electronic component as illustrated in FIG. 8 can be the electronic component 128, 148, or 168, as illustrated in the circuit diagram of FIG. 1.

The second electrode 80 can include one or more layers or other portions. The layer or other portion of the second electrode 80 closest to the organic active layer 74 sets the work function for the second electrode 80. In one embodiment, another layer or other portion of the second electrode 80 includes a black layer, and in another embodiment, another layer or other portion of the second electrode 80 can be used to help reduce resistance within the second electrode 80. In a particular embodiment as illustrated in FIG. 8, the second electrode 80 includes a first layer 82, a second layer 84, and a third layer 86. The materials and potential thicknesses of the first layer 82 and the third layer 86 before addressing the second layer 84.

The first layer 82 can include a low work function material. The low work function layer 82 can include a Group 1 metal (e.g., Li, Cs, etc.), a Group 2 (alkaline earth) metal, a rare earth metal, including the lanthanides and the actinides, an alloy including any of the foregoing metals, a salt of any of the foregoing, or any combination thereof. A conductive polymer with a low work function may also be used. The thickness of the first layer 82 can be in a range of approximately 1 to 100 nm. In one embodiment, the thickness of the first layer 82 is chosen such that the first layer 82 is substantially transparent to radiation at the targeted wavelength or spectrum of wavelengths. In another embodiment, the first layer 82 can have a thickness outside of the range (thinner or thicker).

The third layer 86 may include nearly any conductive material, including those previously described with respect to the first electrode 68. The third layer 86 is used primarily for its ability to allow current to flow while keeping resistance relatively low. An exemplary material for third layer 86 includes aluminum, silver, copper, or any combination thereof. In many applications, the thickness of the third layer 86 may be in a range of approximately 5 to 500 nm. If radiation is not to be transmitted through the second electrode 80, the upper limit on the thickness of the third layer 86 may be greater than 500 nm.

The second layer 84 can include a black layer. The second layer 84 can include one or more elemental metals (e.g., Cr, Ru, Ir, Os, Rh, Pt, Pd, Au, etc.); metal alloys (e.g., Mg—Al, Li—Al, etc.); conductive metal oxides (e.g., RuO₂, IrO₂, OsOₓ, RhOₓ, etc.); conductive metal alloy oxides (e.g., InSnO, AlZnO, AlSnO, etc.); conductive metal nitrides (e.g., WN, TaN, TiN, etc.); conductive metal alloy nitrides (e.g., TiSiN, TaSiN, etc.); conductive metal oxynitrides; conductive metal alloy oxynitrides; doped Group 14 materials (e.g., C (e.g., nanotubes) Si, Ge, SiC, or SiGe); Group 13 to 15 semiconductor materials (e.g., GaAs, InP, or GaInAs); Group 12 to 16 semiconductor materials (e.g., ZnSe, CdS, or ZnSSe); or any combination thereof.

In a particular embodiment, a layer within the second layer 84 may include a material that is conductive in its oxidized and reduced states (e.g., Ru, Ir, Os, Rh, InSn, AlZn, AlSn, etc.). In another particular embodiment, the layer may not significantly react with oxygen when the layer comes in contact with an oxygen-containing material at a temperature higher than room temperature (e.g., 40° C. or higher) during the formation of the layer and any other subsequent fabrication of the electronic device. The oxygen-containing material may include oxygen, water, or ozone from an ambient that is directly exposed to the layer, diffuses to the layer, or may come from a different adjacent layer. In this particular embodiment, the layer can include Pt, Pd, Au, other suitable oxidation-resistant material, or any combination thereof.

In one embodiment, the first layer 82 can be treated as a transparent layer, as previously described, and the third layer 86 may be treated as a mirror that reflects substantially all radiation at the targeted wavelength or spectrum of wavelengths. In one embodiment, after selecting material for the second layer 84, skilled artisans appreciate that the thickness of the second layer 84 can be tailored to achieve low L_{background} using one or more of the equations in Yu. Although the calculations can yield a single thickness, typically a range of acceptable thicknesses may be given for manufacturing reasons. As long as the thickness does not lie outside the range, reasonably acceptable L_{background} may be achieved.

In a particular embodiment, one or more of the equations in Yu may be used for only the second layer 84, by itself, with the second layer 84 in combination with any other layer within the second electrode 80, or the second layer 84 in combination with the first layer 82, the organic layer 70, and the first electrode 68. The refractive index for a material can be obtained from a reference book or using a conventional or proprietary optical technique. Thicknesses for all layers except the second layer 84 may be determined by electronic or optical considerations. Thus, when using one or more of the equations in Yu with a plurality of layers, the thickness of the second layer 84 may be treated as the only variable to achieve low L_{background}. In another embodiment, the material, thickness, or both for any other one or more layers (other than just the second layer 84) may be changed or otherwise varied. Although one or more of the equations in Yu may yield a single thickness, typically a range of acceptable thicknesses may be given for manufacturing reasons. As long as the thickness does not lie outside the range, reasonably acceptable L_{background} may be achieved.

In still another embodiment, the second layer 84 may be an opaque layer with respect to radiation at the targeted wavelength or spectrum of wavelengths over which the electronic device normally operates. One or more inorganic or organic conductive materials can be used for the second layer 84 when it is an opaque layer.

While not meant to be limiting, the thickness of the second layer 84 is typically significantly thinner than the third layer 86. In one embodiment, the thickness of the second layer 84 is in a range of approximately 2 to 100 nm. In another embodiment, the second layer 84 can have a thickness outside of the range (thinner or thicker).

In still another embodiment, more or fewer layers may be used in the second electrode 80. For example, if a layer has a low work function and can be used as a black layer, such layer may replace the combination of the first layer 82 and the second layer 84.

In one embodiment, the second electrode 80 is formed by placing a stencil mask over the substrate 20 and using a conventional or proprietary physical vapor deposition technique to deposit the second electrode 80 as illustrated in FIG. 8. In another embodiment, the second electrode 80 is formed by blanket depositing any individual or combination of the layers 82, 84, and 86 for the second electrode 80. A masking layer (not illustrated) is then formed over portions of the layer(s) that are to remain to form second electrode 80. A conventional or proprietary etching technique is used to remove exposed portions of the layer(s) and leave the second electrode 80. After the etching, the masking layer is removed using a conventional or proprietary technique.

Other circuitry not illustrated, may be formed using any number of the previously described or additional layers. Although not illustrated, additional insulating layer(s) and interconnect level(s) may be formed to allow for circuitry in peripheral areas (not illustrated) that may lie outside the array. Such circuitry may include row or column decoders, strobes (e.g., row array strobe, column array strobe, or the like), sense amplifiers, or any combination thereof.

In FIG. 9, a lid 92 with a desiccant 94 is attached to the substrate 20 at locations (not illustrated in FIG. 9) outside the array to form a substantially completed electronic device. A gap 96 may or may not lie between the second electrode 80 and the desiccant 94. The materials used for the lid and desiccant and the attaching process are conventional or proprietary. The lid 92 typically lies on a side of the electronic device opposite the user side of the electronic device. Still, if desired, radiation may be transmitted through the lid 92 instead of, or in conjunction with, the substrate 20. If so, the lid 92 and desiccant 94 can be designed to allow sufficient radiation to pass through.

A dashed line 98 in FIG. 9 corresponds to a user radiation path. The user radiation path is substantially coterminous with the edge of the black layer 26. To the right of the dashed line 98 in FIG. 9, for a radiation-emitting component, radiation may be emitted by the organic layer 70 that can be seen by a user at the user surface 22 of the electronic device. For a radiation-responsive component, radiation at a targeted wavelength or spectrum of wavelengths from outside the electronic device can be received by the electronic device. To the left of the dashed line 98, radiation at a targeted wavelength or spectrum of wavelengths from inside or outside the electronic device may not be seen by the user of the electronic device due to the black layer 26.

A portion of the control circuit can lie within the user radiation path and another portion can lie outside the user radiation path. Referring to FIG. 9, at least a part of the charge storage component 124 lies within the user radiation path, and at least a part of the power transistor 126 lies outside the user radiation path. In one embodiment, substantially all of the charge storage component 124 lies within the user radiation path, and in another embodiment, part, but not all, of the charge storage component 124 lies within the user radiation path. In still another embodiment, substantially all of the power transistor 126 lies outside the user radiation path, and in yet another embodiment, part, but not all, of the power transistor 126 lies outside the user radiation path. The select transistor 124 (not illustrated) may lie completely or partly within or outside the user radiation path.

6. Operating the Electronic Devices

During operation of a display, appropriate potentials are placed on the first and second electrodes 68 and 80 to cause radiation to be emitted from the organic layer 70. More specifically, when light is to be emitted, a potential difference between the first and second electrodes 68 and 80 allows electron-hole pairs to combine within the organic layer 70, so that light or other radiation may be emitted from the electronic device. In a display, rows and columns can be given signals to activate the appropriate pixels to render a display to a viewer in a human-understandable form.

During operation of a radiation detector, such as a photodetector, sense amplifiers may be coupled to the first electrode 68 or the second electrode 80 of the array to detect significant current flow when radiation is received by the electronic device. In a voltaic cell, such as a photovoltaic cell, light or other radiation can be converted to energy that can flow without an external energy source. After reading this specification, skilled artisans are capable of designing the electronic devices, peripheral circuitry, and potentially remote circuitry to best suit their particular needs.

FIG. 8 includes control circuits that can be used in conjunction with the electronic components, each of which can include a first electrode 68, a second electrode 80, a portion of the first electrode 68 or second electrode 80, or any combination thereof.

7. Alternative Embodiments

In another embodiment, a black layer may be formed at an elevation between a transistor within the control circuit and its corresponding electronic component (e.g., electronic component 128, 148, or 168). FIGS. 10 and 11 include illustrations regarding a particular embodiment having such a black layer.

After partly forming the electronic device as illustrated in FIG. 5, an insulating layer 102 and a black layer 106 are sequentially formed over the substrate 20, as illustrated in FIG. 10. The insulating layer 102 may include any one or more layers that include one or more materials that can be formed using any one or more techniques as described with respect to the insulating layer 62 (see FIG. 6). In one particular embodiment, the insulating layer 102 is relatively thin as compared to the insulating layer 62. In one embodiment, the thickness of the insulating layer 102 is in a range of approximately 2 to 100 nm. The insulating layer 102 may have a thickness outside the range if needed or desired.

The black layer 106 may include any one or more layers that include one or more materials that can be formed using any one or more techniques and may have a thickness as described with respect to the black layer 26 (see FIG. 2). As seen from a top view, the black layer 106 may have substantially the same pattern as compared to the black layer 26. In a particular embodiment, the same stencil mask can be used to achieve the patterns for black layers 26 and 106. In another embodiment, different stencil masks can be used for the black layers 26 and 106. In a particular embodiment, the black layer 26, the black layer 106, or both can be opaque to radiation at the targeted wavelength or spectrum of wavelengths.

Processing continues as substantially described starting with the formation of the insulating layer 62. FIG. 11 includes an illustration after the second electrode 80 is formed. The contact opening 64 extends through the black layer 106 and insulating layer 102 to the conductive member 54. The conductive plug 66 is formed within the contact opening as previously described.

If the black layer 106 is not resistive enough, undesired electrical connections or leakage paths may be formed between electronic components within the same or different pixels or even subpixels. Thus, in one particular embodiment, an insulating spacer (not illustrated) can be formed within contact opening 64 before forming the conductive plug 66. The insulating spacer helps to electrically insulate the black layer 106 from the conductive plug 66 while still allowing electrical contact to be made to the conductive member 54. The insulating spacer can be formed using any one or more conventional or proprietary deposition and etch techniques as used in the inorganic semiconductor arts.

In still another embodiment (not illustrated), the first electrode 68 may include a black layer instead of, or in conjunction with, the second layer 84 within the second electrode 80. The black layer within the first electrode 68 allows for a significant amount of radiation to be transmitted through it so that the organic active layer 74 can emit or receive radiation. Therefore, in this embodiment, the black layer within the first electrode 68 is not an opaque layer. Otherwise, the material, formation technique, and thickness for the black layer within the first electrode 68 may be any one or more materials, formation techniques, or thicknesses as used for the second layer 84 of the second electrode 80. When the black layer within the first electrode 68 and the second layer 84 within the second electrode 80 are both included in a device, they may be formed using the same or different materials, techniques, thicknesses, or any combination thereof. In still another embodiment, the positional relationships of the first electrode 68 and the second electrode 80 may be reversed. In this embodiment, the second electrode 80 would lie closer to the user surface 22. In other embodiments, the first and second electrodes 68 and 80 can be reversed. In this embodiment, the second electrode 80 would lie closer to the substrate 20, as compared to the first electrode 68. The second electrode 80 could include a plurality of second electrodes that are each connected to control circuits (not illustrated). Also, the first electrode 68 could be replaced by a common first electrode. In still another alternative embodiment, the control circuits may be connected to one type of electrode that lies farther from the substrate 20 as compared to the other type of electrode. The first electrode 68, the second electrode 80, or both may include a black layer.

The concepts described herein can be extended to other electronic devices, such as LCDs. The black layers 26 and 106 can be used to reduce radiation, such as radiation within the visible light spectrum, from reaching a transistor within a control circuit for a liquid crystal. The electronic component 128, 148, 168, or any combination thereof would be replaced by one or more liquid crystals. In still other embodiments, the concepts described herein may be extended to other displays, such as those including inorganic semiconductors, or other applications in which contrast ratio is to be kept relatively high.

8. Benefits

The use of the black layer 26 and the second layer 84, which can also be a black layer, can provide a cost-effective, manufacturable solution to provide relatively higher contrast compared to conventional electronic devices. The black layer 26 can help to reduce reflection from electronic components within the control circuit (e.g., transistors), and the second layer 84 can help to reduce reflection from the third layer 86 within the second electrode. A black layer within the first electrode 68 may serve a similar purpose as the second layer 84 within the second electrode 80, and therefore, the first electrode 68, the second electrode 80, or both may include a black layer.

The embodiments may obviate the need for a circular polarizer. Low L_{background} can be achieved by designing the electronic device for low reflectivity. The layers affected do not significantly affect the overall thickness of the electronic device.

Embodiments as described herein can provide a cost-effective, manufacturable solution to provide low L_{background} compared to conventional electronic devices because existing materials may be used within an electronic device without requiring the replacement of current materials within the electronic device regions. The ability to use the current materials simplifies integration and reduces the likelihood of device re-design, materials compatibility issues, or device reliability issues.

Electronic device performance may be improved by having one or more black layers near at least parts of the control circuits for the pixels or subpixels. In one embodiment, part or all of the select and power transistors 122 and 126 may be protected from ambient radiation by the black layer 26. A field-effect transistor may have different electrical characteristics when its channel region (e.g., within semiconductor layer 44) is exposed to ambient radiation as compared to when its channel region is not exposed to ambient radiation. Ambient radiation may cause electron-hole pairs to generate within the channel region and cause leakage current to be higher when the transistor is to be off or otherwise biased to achieve a low current flow through the channel region.

If the select transistor 122 is off and its channel region is exposed to ambient radiation, higher leakage current can result in adversely losing or gaining charge within the charge storage component 124. The change in charge can affect the voltage on the gate electrode of the power transistor 126, which in the case of a radiation-emitting component, can change the intensity of radiation from that component and potentially affect color balance within the pixel.

If the power transistor 126 is off or its gate electrode is otherwise at its lowest operating potential and its channel region is exposed to ambient radiation, higher current than desired may be flowing through the power transistor 126. For a radiation-emitting component coupled to the power transistor 126, the higher current can adversely affect the intensity of radiation from that component and potentially affect color balance within the pixel. Thus, the black layer 26 may help to reduce current within transistors 122 and 126 when those transistors are in an off or low current mode of operation.

In another embodiment, the black layer 106 can reduce radiation from reaching the power transistor 126 within the electronic device. In a particular embodiment where the electronic component is a radiation-emitting component, the black layer 106 can help to reduce the intensity or prevent radiation from reaching the power transistor 126, and particularly its channel region within the semiconductor layer 44. Even if a black layer is not present within either of the electrodes, the black layers 26 and 106 can help to reduce radiation reaching the transistors within the control circuit, regardless of whether the radiation is ambient radiation, coming from the control circuit's corresponding radiation-emitting component, coming from another radiation-emitting component within a different subpixel or pixel, or any combination thereof.

The use of the black layer 26, black layer 106, or both can be used to help reduce radiation from a backlight within an LCD is a manner similar to that described with respect to an OLED display.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

What is claimed is:

1. An electronic device comprising:
a control circuit of a pixel;
a first black layer including an opening; and
a second black layer, wherein the control circuit lies at an elevation between the first black layer and the second black layer.

2. The electronic device of claim 1, wherein the pixel comprises a first electrode, wherein the first electrode:
includes a portion of the second black layer; and
is electrically coupled to the control circuit.

3. The electronic device of claim 2, wherein the pixel further comprises a second electrode that is electrically connected to the control circuit.

4. The electronic device of claim 1, further comprising a substrate including a user surface that lies closer to the first black layer as compared to the second black layer.

5. The electronic device of claim 1, wherein:
the opening within the first black layer corresponds to a user radiation path of the pixel, wherein at least a portion of the control circuit lies within the user radiation path of the pixel; and
the control circuit comprises a power transistor that includes a channel region, wherein at least a majority of the channel region lies outside the user radiation path.

6. The electronic device of claim 5, wherein the control circuit comprises a charge storage component, wherein at least a portion of the charge storage component lies within the user radiation path of the pixel.

7. The electronic device of claim 6, wherein:
at least a majority of the charge storage component lies within the user radiation path; and
substantially all of the channel region lies outside the user radiation path.

8. The electronic device of claim 1, wherein the first black layer, the second black layer, or both are substantially opaque to radiation within the visible light spectrum.

9. The electronic device of claim 1, wherein the pixel comprises an organic active layer.

10. The electronic device of claim 1, further comprising a substrate having a user side, wherein:
the pixel comprises a first electrode and a second electrode;
the second electrode is electrically connected to the control circuit; and
each of the first and second electrodes lie farther from the user side of the substrate as compared to each of the first and second black layers.

11. The electronic device of claim 10, wherein the second black layer comprises an opening corresponding to an emissive radiation path of the pixel, wherein at least a portion of the control circuit lies outside the emissive radiation path of the pixel.

12. The electronic device of claim 11, wherein the control circuit comprises a power transistor that includes a channel region, wherein at least a majority of the channel region lies outside the emissive radiation path.

13. The electronic device of claim 12, wherein the control circuit comprises a charge storage component, wherein at least a portion of the charge storage component lies within the emissive radiation path of the pixel.

14. The electronic device of claim 13, wherein:
at least a majority of the charge storage component lies within the emissive radiation path; and
substantially all of the channel region lies outside the emissive radiation path.

15. A process of forming an electronic device comprising:
forming a first black layer over a substrate, wherein the first black layer includes an opening;
forming a control circuit of a pixel over the substrate after forming the first black layer; and
forming a second black layer over the substrate after forming the control circuit.

16. The process of claim 15, further comprising:
forming a first electrode after forming the control circuit and before forming the second black layer; and
forming a second electrode after forming the first electrode, wherein forming the second electrode includes forming the second black layer.

17. The process of claim 15, wherein the first electrode is electrically connected to the control circuit.

18. The process of claim 15, wherein:
the second black layer comprises an opening that is substantially coterminous with the opening of the first black layer; and
the process further comprises:
forming a first electrode after forming the control circuit and forming the second black layer; and
forming a second electrode after forming the first electrode.

19. The process of claim 15, wherein the electronic device is configured to emit radiation or respond to radiation transmitted through the substrate.

20. The process of claim 15, further comprising forming an organic active layer over the substrate after forming the first black layer and forming the control circuit.
